(19) United States
(12) Patent Application Publication
(10) Pub. No.: US 2026/0343940 A1
(43) Pub. Date: Oct. 29, 2026

(54) POWER METAL-OXIDE-SEMICONDUCTOR FIELD-EFFECT TRANSISTOR AND METHOD FOR MANUFACTURING THE SAME

(71) Applicant: Leadpower-semi CO., LTD., Zhubei City (TW)

(72) Inventors: Po-Hsien LI, Taipei City (TW); Shih-Jung ZHAN, Zhubei City (TW); Chia-Sheng SU, Zhubei City (TW); Jen-Hao YEH, Zhubei City (TW)

(21) Appl. No.: 19/344,687

(22) Filed: Sep. 30, 2025

(30) Foreign Application Priority Data
Apr. 25, 2025 (TW) 114115800

(51) Int. Cl. H10D 30/66; H10D 30/01; H10D 62/10; H10D 64/23; H10D 64/27; H10D 64/66

(52) U.S. Cl. CPC H10D 30/668; H10D 30/0295; H10D 30/0297; H10D 62/102; H10D 62/124; H10D 64/2527; H10D 64/516; H10D 64/661

(57) ABSTRACT

A power metal-oxide-semiconductor field-effect transistor (MOSFET) includes a drain electrode, a drift layer, a trench-type structure, and a planar-type structure. The drift layer is disposed on the drain electrode and has a first region and a second region. The trench-type structure is located at the first region and includes a gate trench, a trench gate electrode located in the gate trench, two first well regions respectively disposed at two opposite sides of the trench gate electrode, and two first source electrodes respectively located in the two first well regions. The planar-type structure is located at the second region and includes a planar gate electrode, at least two second well regions respectively disposed at two opposite sides of the planar gate electrode, and at least two second source electrodes respectively located in the at least two second well regions. A method for manufacturing the power MOSFET is also disclosed.

### CROSS-REFERENCE TO RELATED APPLICATION

This application claims priority to Taiwanese Invention Patent Application No. 114115800 filed on Apr. 25, 2025, the entire disclosure of which is incorporated by reference herein.

### FIELD

The disclosure relates to a semiconductor device, and more particularly to a power metal-oxide-semiconductor field-effect transistor.

### BACKGROUND

In order to achieve a high output power density and a faster switching frequency, a power metal-oxide-semiconductor field-effect transistor (power MOSFET) is usually designed with a trench gate configuration (see FIG. 2), which reduces a channel length, rather than with a planar gate configuration (see FIG. 1). The trench gate configuration enables the power MOSFET to have a higher device density, a reduced on-state resistance between a source electrode and a drain electrode (R_{DSON}), and a reduced input capacitance (Cᵢₛₛ).

Referring to FIG. 3, a safe operating area (SOA) is one of the essential characteristics to be considered in the power MOSFET. The SOA may be determined by an R_{DSON} limit, a package limit, a maximum power limit, a thermal stability limit and a breakdown voltage limit in a current-voltage (I-V) characteristic of the power MOSFET. The power MOSFET is relatively stable and is less likely to be damaged when the SOA is larger.

The power MOSFET with the trench gate configuration may exhibit superior properties on the R_{DSON} limit, the package limit, the maximum power limit, and the breakdown voltage limit, but it often has poor thermal stability. In contrast, although the power MOSFET with the planar gate configuration may exhibit undesired properties in various aspects and has a higher R_{DSON} compared to that with the trench gate configuration, it has relatively good thermal stability. Thus, there is still a need to develop a power MOSFET with a relatively large SOA and a relatively low R_{DSON} while also exhibiting improved thermal stability.

### SUMMARY

Therefore, an object of the disclosure is to provide a power metal-oxide-semiconductor field-effect transistor that can alleviate at least one of the drawbacks of the prior art.

According to a first aspect of the disclosure, a power metal-oxide-semiconductor field-effect transistor includes a drain electrode, a drift layer, a trench-type structure and a planar-type structure. The drain electrode has a surface extending along a first direction and a second direction perpendicular to the first direction. The drift layer is disposed on the drain electrode and has a first region and a second region that are arranged along the first direction. The trench-type structure is located at the first region of the drift layer, and includes a gate trench, a trench gate unit, two first well regions, and two first source electrodes. The gate trench is recessed from an upper surface of the drift layer. The trench gate unit includes a trench gate electrode located in the gate trench. The two first well regions are located in the first region of the drift layer and are respectively disposed at two opposite sides of the trench gate electrode in the first direction. The two first source electrodes are respectively located in the two first well regions. The planar-type structure is located at the second region of the drift layer, and includes a planar gate electrode, at least two second well regions, and at least two second source electrodes. The planar gate electrode is disposed on the second region of the drift layer. The at least two second well regions are located in the second region of the drift layer and are respectively disposed at two opposite sides of the planar gate electrode in the second direction. The at least two second source electrodes are respectively located in the at least two second well regions. The trench-type structure and the planar-type structure are electrically connected with each other in parallel.

According to a second aspect of the disclosure, a method for manufacturing a power metal-oxide-semiconductor field-effect transistor includes: forming a drift layer on a surface of a drain electrode, the surface of the drain electrode extending along a first direction and a second direction perpendicular to the first direction, the drift layer having a first region and a second region that are arranged along the first direction; etching the drift layer along a third direction that is transverse to the first direction and the second direction to form a gate trench in the first region of the drift layer; forming a trench gate electrode in the gate trench and a planar gate electrode on the second region of the drift layer; forming two first well regions that are located in the first region of the drift layer, that are respectively disposed at two opposite sides of the trench gate electrode in the first direction, and that have a first type conductivity; forming two second well regions that are located in the second region of the drift layer, that are respectively disposed at two opposite sides of the planar gate electrode in the second direction, and that have the first type conductivity; forming two first source electrodes that are respectively located in the two first well regions and that have a second type conductivity; and forming two second source electrodes that are respectively located in the two second well regions and that have the second type conductivity.

### BRIEF DESCRIPTION OF THE DRAWINGS

Other features and advantages of the disclosure will become apparent in the following detailed description of the embodiment(s) with reference to the accompanying drawings. It is noted that various features may not be drawn to scale.

FIG. 1 is a schematic view illustrating a conventional power metal-oxide-semiconductor field-effect transistor (MOSFET) with a planar gate configuration.

FIG. 2 is a schematic view illustrating a conventional power MOSFET with a trench gate configuration.

FIG. 3 is a safe operating area (SOA) diagram of a conventional power MOSFET.

FIG. 4 is a fragmentary perspective view illustrating an embodiment of a power MOSFET of the present disclosure.

FIG. 5 is a cross-sectional view illustrating a planar-type structure of the embodiment of the power MOSFET.

FIG. 6 is a current-voltage (I-V) characteristic diagram of the embodiment of the power MOSFET.

FIG. 7 is a cross-sectional view of an embodiment of the power MOSFET of the present disclosure.

FIG. 8 is a cross-sectional view of an embodiment of the power MOSFET of the present disclosure.

FIG. 9 is a flow diagram illustrating a method for manufacturing the embodiment of the power MOSFET.

FIGS. 10 to 15 are schematic views illustrating intermediate stages of the method for manufacturing the embodiment of the power MOSFET shown in FIG. 4.

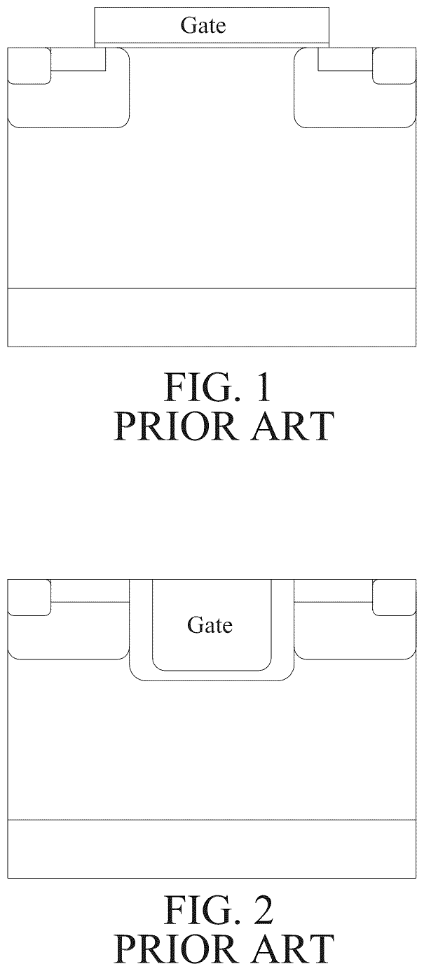

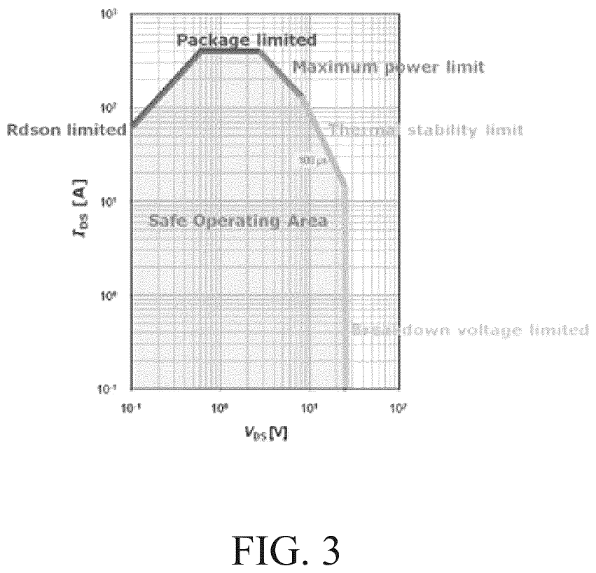

### DETAILED DESCRIPTION

Before the disclosure is described in greater detail, it should be noted that where considered appropriate, reference numerals or terminal portions of reference numerals have been repeated among the figures to indicate corresponding or analogous elements, which may optionally have similar characteristics.

It should be noted herein that for clarity of description, spatially relative terms such as “top,” “bottom,” “upper,” “lower,” “on,” “above,” “over,” “downwardly,” “upwardly” and the like may be used throughout the disclosure while making reference to the features as illustrated in the drawings. The features may be oriented differently (e.g., rotated 90 degrees or at other orientations) and the spatially relative terms used herein may be interpreted accordingly.

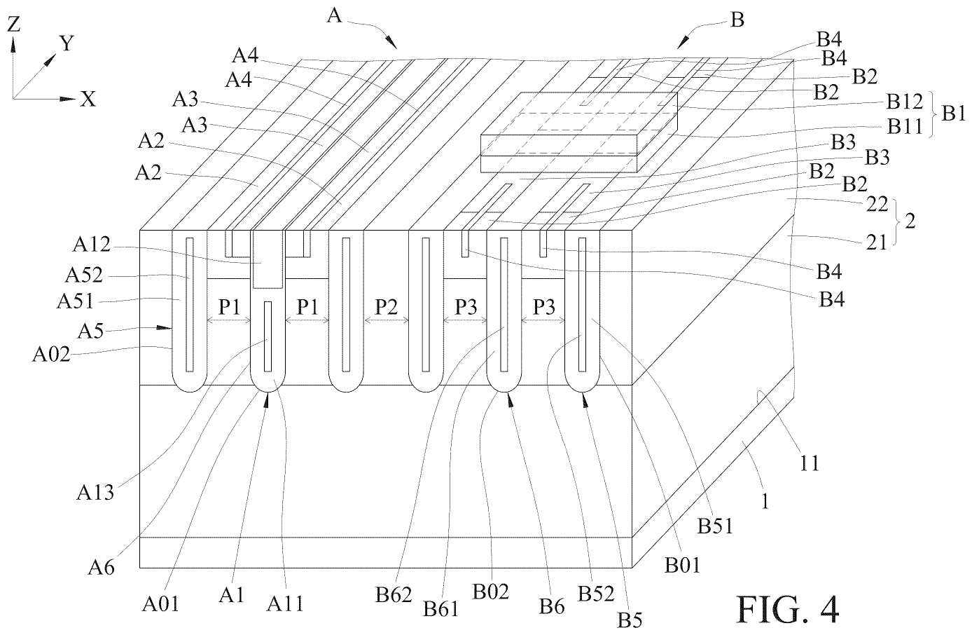

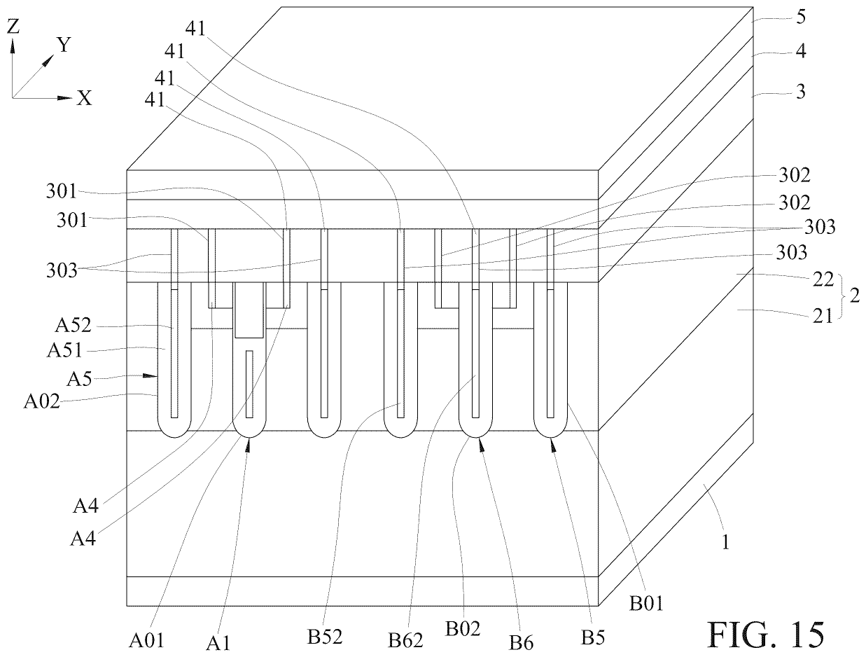

Referring to FIGS. 4 and 15, an embodiment of a power metal-oxide-semiconductor field-effect transistor (MOSFET) of this disclosure includes a drain electrode 1, a drift layer 2, an inner dielectric layer 3, a source metal layer 4, and a passivation layer 5.

The drain electrode 1 has a surface 11 which extends along a first direction (X) and a second direction (Y) that is perpendicular to the first direction (X). The drain electrode 1, the drift layer 2, the inner dielectric layer 3, the source metal layer 4, and the passivation layer 5 are sequentially arranged in a third direction (Z) that is transverse to the first direction (X) and the second direction (Y). In some embodiments, the drift layer 2 includes a lower layer 21 and an upper layer 22 that is formed on the lower layer 21 in the third direction (Z). The upper layer 22 has a doping concentration that is greater than a doping concentration of the lower layer 21 so that a power MOSFET of the present disclosure may exhibit improved performance. The drift layer 2 is disposed on the drain electrode 1 and has a first region and a second region that are arranged along the first direction (X). In some embodiments, the drift layer 2 further includes a third region that is located between the first region and the second region. The power MOSFET may include a trench-type structure (A) and a planar-type structure (B). The trench-type structure (A) is located at the first region of the drift layer 2, and the planar-type structure (B) is located at the second region of the drift layer 2, so the third region is located between the trench-type structure (A) and the planar-type structure (B) in the first direction.

The trench-type structure (A) includes a gate trench (A01) that is recessed from an upper surface of the drift layer 2, a trench gate unit (A1) that includes a trench gate electrode (A12) located in the gate trench (A01), two first well regions (A2) that are located in the first region of the drift layer 2, two first source electrodes (A3) that are located in the first region of the drift layer 2, two first conductive layers (A4), and a first terminal structure (A5). The gate trench (A01) of the trench-type structure (A) is defined by a surrounding wall (A6). The trench gate unit (A1) further includes a first isolation layer (A11) and a shield electrode (A13). The first isolation layer (A11) is made of an insulating material, and extends along and covers the surrounding wall (A6). The trench gate electrode (A12) is surrounded by the first isolation layer (A11). The shield electrode (A13) is also surrounded by the first isolation layer (A11), and spaced apart from the trench gate electrode (A12) by the first isolation layer (A11) in the third direction (Z). The two first well regions (A2) are respectively disposed at two opposite sides of the trench gate electrode (A12) in the first direction (X). The two first source electrodes (A3) are respectively located in the first well regions (A2). The first conductive layers (A4) are respectively in electrical communication with the first source electrodes (A3). In some embodiments, the first isolation layer (A11) is made of an oxide material. In certain embodiments, the oxide material is silicon oxide.

The first terminal structure (A5) surrounds the trench gate unit (A1), the first well regions (A2), the first source electrodes (A3), and the first conductive layers (A4). The first terminal structure (A5) includes a first ring-shaped trench (A02), a first insulating layer (A51), and a first electrode layer (A52). The first ring-shaped trench (A02) is recessed from the upper surface of the drift layer 2. The first insulating layer (A51) and the first electrode layer (A52) are located in the first ring-shaped trench (A02). In some embodiments, the first insulating layer (A51) is made of an oxide material. In certain embodiments, the oxide material is silicon oxide.

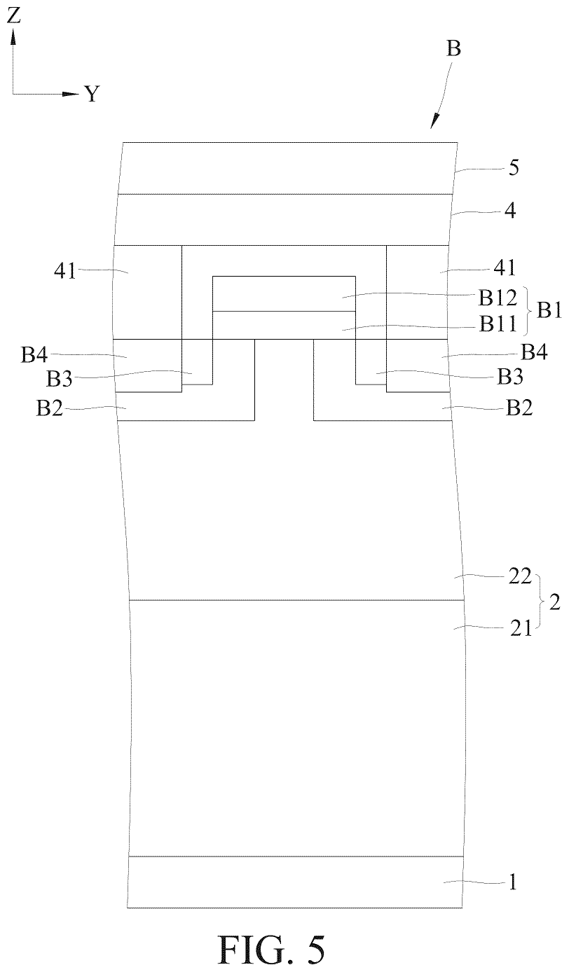

Referring to FIGS. 4 and 5, the planar-type structure (B) is electrically connected to the trench-type structure (A) in parallel, and includes a planar gate unit (B1), at least two second well regions (B2), at least two second source electrodes (B3), at least two second conductive layers (B4), a second terminal structure (B5), and a third terminal structure (B6). The planar gate unit (B1) may include a gate oxide layer (B11) and a planar gate electrode (B12) that is disposed on the gate oxide layer (B11). The planar gate electrode (B12) spans across the at least two second well regions (B2). In some embodiments, the at least two second well regions (B2) include four second well regions (B2), the at least two second source electrodes (B3) include four second source electrodes (B3), and the at least two second conductive layers (B4) include four second conductive layers (B4). In some embodiments, the second well regions (B2) are located in the second region of the drift layer 2 and are respectively disposed at two opposite sides of the planar gate electrode (B12) in the second direction (Y). The second source electrodes (B3) are respectively located in the second well regions (B2). In greater detail, the four second well regions (B2) are formed in two pairs which are located below and disposed at the two opposite sides of the planar gate electrode (B12) and which are arranged opposite to each other in the second direction (Y). Among each of the two pairs, two of the second well regions (B2) are spaced apart from each other in the first direction (X). In some embodiments, the gate oxide layer (B11) is made of an insulated oxide material.

The second terminal structure (B5) is formed in the drift layer 2 to surround the second well regions (B2), the second source electrodes (B3), and the second conductive layers (B4). The second terminal structure (B5) is disposed beneath the planar gate electrode (B12). The second terminal structure (B5) includes a second ring-shaped trench (B01) recessed from the upper surface of the drift layer 2, a second insulating layer (B51), and a second electrode layer (B52). The second insulating layer (B51) and the second electrode layer (B52) are located in the second ring-shaped trench (B01). The third terminal structure (B6) is surrounded by the second terminal structure (B5) and extends along the second direction (Y). In some embodiments, the second well regions (B2) in each of the pairs are spaced apart from each other in the first direction (X) by the third terminal structure (B6). The four second source electrodes (B3) are respectively disposed in the second well regions (B2), and also formed in two pairs corresponding to the pairs of the second well regions (B2). Among each of the two pairs, two of the second source electrodes (B3) are spaced apart from each other in the first direction (X) by the third terminal structure (B6). The third terminal structure (B6) includes a groove (B02) recessed from the upper surface of the drift layer 2, a third insulating layer (B61), and a third electrode layer (B62). The third insulating layer (B61) and the third electrode layer (B62) are located in the groove (B02). The planar gate electrode (B12) is disposed on the third terminal structure (B6). In some embodiments, each of the second insulating layer (B51) and the third insulating layer (B61) is made of an oxide material. In certain embodiments, the oxide material is silicon oxide.

It should be noted that, for ease of illustration, FIG. 4 only shows a partial structure of this embodiment. However, from a top perspective view, both the first terminal structure (A5) and the second terminal structure (B5) are annular in shape, while the third terminal structure (B6) is in the form of a strip.

In greater detail, in the drift layer 2, the third region is located between the first ring-shaped trench (A02) and the second ring-shaped trench (B01). The third region may serve as a buffer region to prevent interference between the trench-type structure (A) and the planar-type structure (B) during the operation.

In some embodiments, an area (TA1) of a projection of the trench-type structure (A) onto the surface 11 of the drain electrode 1 is greater than an area (TA2) of a projection of the planar-type structure (B) on the surface 11 of the drain electrode 1, so that desired characteristics of the trench-type structure (A) (e.g., an on-state resistance between a source electrode and a drain electrode (R_{DSON}) limit, a package limit, a maximum power limit, a breakdown voltage limit, etc.) may be obtained with inclusion of desired thermal stability that is featured by the planar-type structure (B).

In some embodiments, a percentage of the area (TA1) of the projection of the trench-type structure (A) over an area of the surface 11 of the drain electrode 1 is not less than 60%. In some embodiments, a percentage of the area (TA2) of the projection of the planar-type structure (B) over the area of the surface 11 of the drain electrode 1 is not greater than 40%. In some embodiments, a percentage of an area of a projection of the third region onto the surface 11 of the drain electrode 1 over the area of the surface 11 of the drain electrode 1 is not greater than 5%.

Referring to FIG. 4, in the first direction (X), the first ring-shaped trench (A02) and the gate trench (A01) are separated from each other by a first distance (P1). The first ring-shaped trench (A02) and the second ring-shaped trench (B01) are separated from each other by a second distance (P2). The second ring-shaped trench (B01) and the groove (B02) are separated from each other by a third distance (P3). In some embodiments, the first distance (P1), the second distance (P2), and the third distance (P3) are identical so that a breakdown voltage of drain-to-source (BV_{DSS}) of the power MOSFET may be effectively controlled.

In some embodiments, the first source electrodes (A3) of the trench-type structure (A) are spaced apart from each other in the first direction (X), and the at least two second source electrodes (B3) are arranged opposite to each other in the second direction (Y), so that a channel length in the planar-type structure (B) may not be restricted by the third distance (P3). In addition, channels in the planar-type structure (B) are located between the pairs of the second source electrodes (B3) which are electrically connected with each other in parallel in the first direction (X), so that an effective area of the

### Planar-type Structure (b) May Be Increased.

Referring to FIG. 15, the inner dielectric layer 3 is disposed on the trench-type structure (A) and the planar-type structure (B). The source metal layer 4 is located on the inner dielectric layer 3 opposite to the drift layer 2. The inner dielectric layer 3 includes first through holes 301, second through holes 302, and third through holes 303, each of which penetrates the inner dielectric layer 3. The number of the first through holes 301 and positions thereof correspond to those of the first conductive layers (A4). The number of the second through holes 302 and positions thereof correspond to those of the second conductive layers (B4). The third through holes 303 correspond to the first electrode layer (A52) of the first terminal structure (A5), the second electrode layer (B52) of the second terminal structure (B5), and the third electrode layer (B62) of the third terminal structure (B6) in number and position. The power MOSFET includes conductive plugs 41 respectively filling the first through holes 301, the second through holes 302, and the third through holes 303. The source metal layer 4 is in electrical communication with the first conductive layers (A4), the second conductive layers (B4), the first electrode layer (A52), the second electrode layer (B52), and the third electrode layer (B62) through the conductive plugs 41. The passivation layer 5 is disposed on the source metal layer 4.

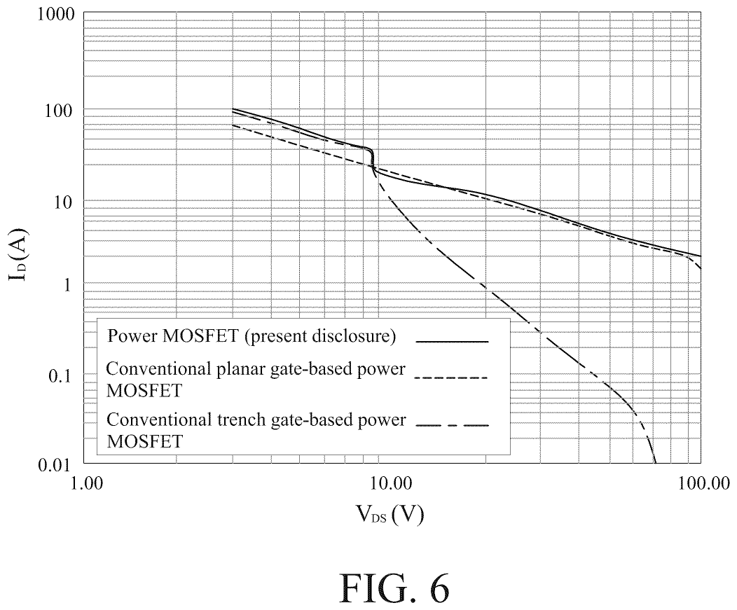

FIG. 6 is a diagram showing current-voltage (I-V) characteristics of a conventional planar gate-based power MOSFET, a conventional trench gate-based power MOSFET, and the embodiment of the power MOSFET of the present disclosure. In the diagram, the conventional planar gate-based power MOSFET exhibits a relatively large R_{DSON}, and thus a drain current (I_{D}) is relatively small when a drain-source voltage (V_{DS}) is smaller than 10 V. However, it is able to provide a relatively high I_{D} when the V_{DS} ranges from 10 V to 100 V, suggesting that it has relatively good thermal stability. In the diagram, the conventional trench gate-based power MOSFET exhibits a relatively low R_{DSON}, and thus an I_{D} obtained therefrom is relatively large when the V_{DS} is smaller than 10 V. However, when the V_{DS} is larger than 10 V, the I_{D} obtained therefrom is significantly reduced; when the V_{DS} is about 70 V, the I_{D} is reduced to 0.01 A. These results suggest that the conventional trench gate-based power MOSFET exhibits undesired thermal stability. The embodiment of the power MOSFET of the present disclosure, which includes the trench gate unit (A1) and the planar gate unit (B1) that are electrically connected with each other in parallel, exhibits a relatively low R_{DSON} and relatively good thermal stability. When the V_{DS} is smaller than 10 V, it has an I_{D} that is at a level similar to that of the conventional trench gate-based power MOSFET. When the V_{DS} ranges from 10 V to 100 V, it exhibits an I_{D} that is at a level similar to that of the conventional planar gate-based power MOSFET.

It should be noted that the number of each of the second well regions (B2) and the second source electrodes (B3) is four in this embodiment. However, the number of each of the second well regions (B2) and the second source electrodes (B3) may vary based on actual requirements, and in certain embodiments, it may be two.

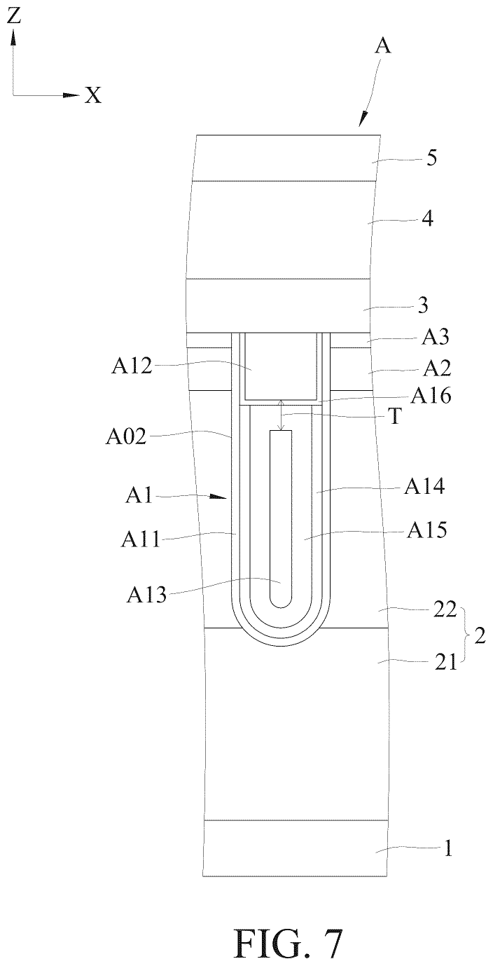

FIG. 7 shows a cross-sectional view of a variant structure of the power MOSFET in accordance with some embodiments, which has a structure similar to the embodiment shown in FIG. 4 except for the trench gate unit (A1) of the trench-type structure (A).

In the variant structure of the power MOSFET, the trench gate electrode (A1) further includes a second isolation layer (A14), a third isolation layer (A15), and a fourth isolation layer (A16). The second isolation layer (A14) and the third isolation layer (A15) are sequentially formed on the first isolation layer (A11) and are located between the first isolation layer (A11) and the shield electrode (A13). The second isolation layer (A14) is made of a nitride-based material. Each of the third isolation layer (A15) and the fourth isolation layer (A16) is made of an oxide material. The third isolation layer (A15) covers (e.g., encloses) the shield electrode (A13). The fourth isolation layer (A16) is located between the trench gate electrode (A12) and the first isolation layer (A11), and covers surfaces of the trench gate electrode (A12) except for an upper surface of the trench gate electrode (A12) which is away from the shield electrode (A13). The trench gate electrode (A12) and the shield electrode (A13) are separated from each other by the third isolation layer (A15) and the fourth isolation layer (A16) by a distance (T) in the third direction (Z). In some embodiments, the distance (T) ranges from 500 Å to 4000 Å.

The fourth isolation layer (A16) covers the surfaces of the trench gate electrode (A12) that are proximate to the shield electrode (A13), so that the trench gate electrode (A12) and the second isolation layer (A14) made from the nitride-based material are separated from each other. Thus, the performance of the power MOSFET may not be adversely affected by contact between the trench gate electrode (A12) and the nitride-based material, or interaction occurring due to excessive proximity between the trench gate electrode (A12) and the nitride-based material.

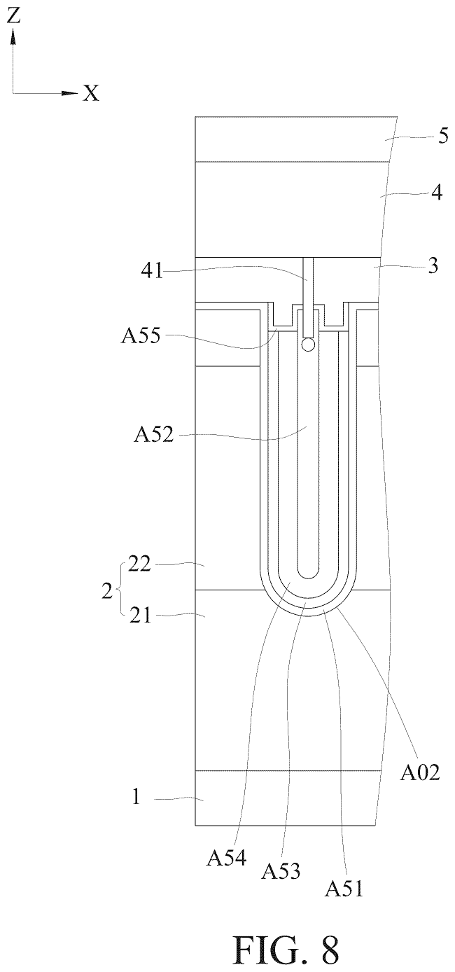

FIG. 8 shows a cross-sectional view of a variant structure of the power MOSFET in accordance with some embodiments, which has a structure similar to the embodiment shown in FIG. 4 except for the first terminal structure (A5).

To be specific, in the variant structure of the power MOSFET, the first terminal structure (A5) further includes a protection layer (A53), a second insulating layer (A54) and a third insulating layer (A55). The protection layer (A53) and the second insulating layer (A54) are sequentially formed on the first insulating layer (A51) and are located between the first insulating layer (A51) and the first electrode layer (A52). The protection layer (A53) is made of a nitride-based material. The second insulating layer (A54) is formed between the protection layer (A53) and the first electrode layer (A52) so that the protection layer (A53) is spaced apart from the first electrode layer (A52). The third insulating layer (A55) covers upper surfaces of the first electrode layer (A52), the protection layer (A53), and the second insulating layer (A54). The third insulating layer (A55) is penetrated by a corresponding one of the conductive plugs 41 in the third direction (Z), so that the first electrode layer (A52) is in electrical communication with the corresponding one of the conductive plugs 41. In some embodiments, each of the second insulating layer (A54) and the third insulating layer (A55) is made of an oxide material.

The protection layer (A53) made of the nitride-based material may protect the first insulating layer (A51) and prevent the oxide material of the first insulating layer (A51) from being oxidized in subsequent thermal processes. In addition, the first electrode layer (A52) and the protection layer (A53) are separated from each other by the second insulating layer (A54). Thus, the nitride-based material of the protection layer (A53) and the first electrode layer (A52) may not interact with each other to generate charges which may reduce the performance and reliability of the power MOSFET.

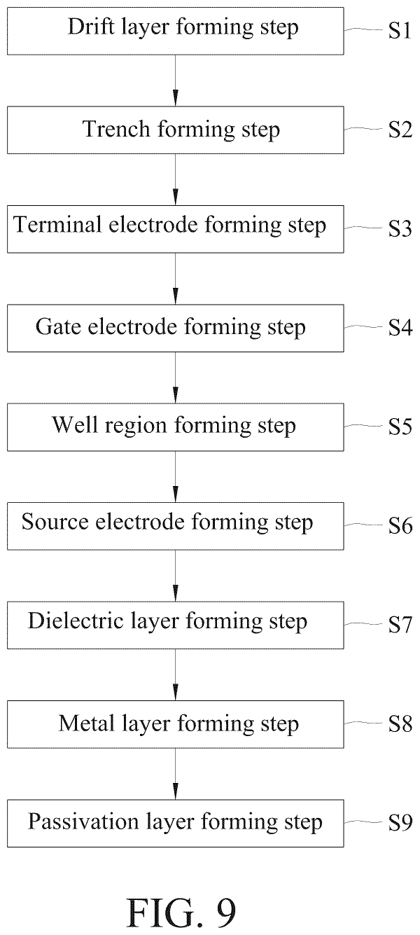

An embodiment of a method for manufacturing the embodiment of the power MOSFET shown in FIG. 15 is provided, and is exemplified in FIGS. 9 to 15.

Referring to FIG. 9, the method for manufacturing the power MOSFET includes a drift layer forming step (S1), a trench forming step (S2), a terminal electrode forming step (S3), a gate electrode forming step (S4), a well region forming step (S5), a source electrode forming step (S6), a dielectric layer forming step (S7), a metal layer forming step (S8), and a passivation layer forming (S9). It should be noted that additional steps may be provided before, after or during the method.

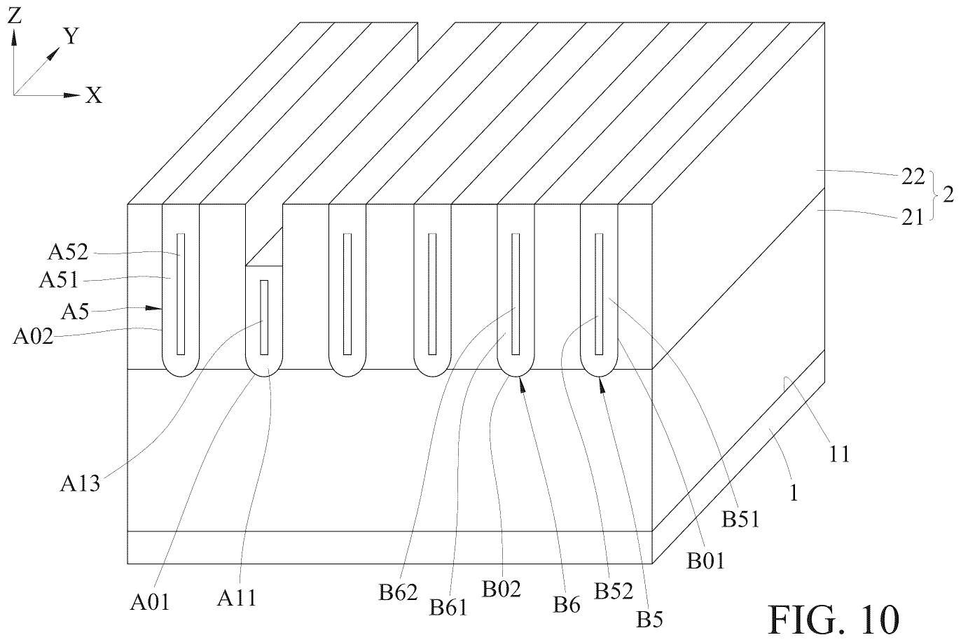

Referring to FIG. 10, in the drift layer forming step (S1), the drift layer 2 is formed on the surface 11 of the drain electrode 1. The surface 11 of the drain electrode 1 extends along the first direction (X) and the second direction (Y) that is perpendicular to the first direction. In the trench forming step (S2), the drift layer 2 is etched along the third direction (Z) so as to form the gate trench (A01) in the first region of the drift layer 2, the first ring-shaped trench (A02) in the first region of the drift layer 2, the second ring-shaped trench (B01) in the second region of the drift layer 2, and the groove (B02) in the second region of the drift layer 2.

In the terminal electrode forming step (S3), a first insulation material, an electrode material, and a second insulation material (may be the same as the first insulation material) are sequentially deposited on the upper surface of the drift layer 2 and in the gate trench (A01), the first ring-shaped trench (A02), the second ring-shaped trench (B01), and the groove (B02). Next, portions of the first and second insulation materials and a portion of the electrode material, which are located on the drift layer 2 are removed so as to form the first terminal structure (A5), the second terminal structure (B5), and the third terminal structure (B6) in the drift layer 2.

In some embodiments, in the terminal electrode forming step (S3), in the gate trench (A01), after depositing the first insulation material and the electrode material, a patterning process (e.g., a process that includes a photolithography process followed by an etching process) may be performed to remove portions of the first insulation material and the electrode material located in the gate trench (A01). Then, the second insulation material is deposited to cover remaining portions of the first insulation material and the electrode material, so that the remaining portion of the first insulation material, second insulation material, and the remaining portion of the electrode material deposited in the gate trench (A01) are formed into the first isolation layer (A11) and the shield electrode (A13). As such, as shown in FIG. 10, the first isolation layer (A11) and the shield electrode (A13) do not completely fill the gate trench (A01).

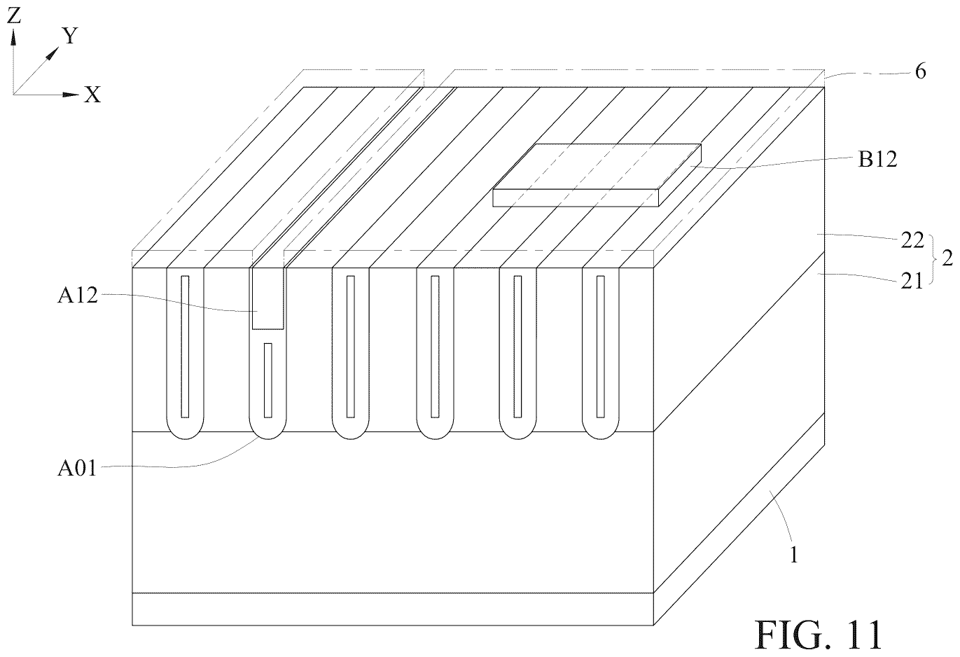

Referring to FIG. 11, in the gate electrode forming step (S4), the drift layer 2 shown in FIG. 10 is subjected to a thermal process so that a portion of the upper layer 22 cooperatively with a portion of the first insulating layer (A51) is formed into an oxide layer 6. Then, a gate electrode material is deposited on the oxide layer 6 and in the gate trench (A01). Subsequently, a portion of the gate electrode material on the oxide layer 6 is removed so that the trench gate electrode (A12) is formed in the gate trench (A01) and the planar gate electrode (B12) is formed on the second region of the drift layer 2. The gate electrode material for forming the trench gate electrode (A12) and the planar gate electrode (B12) may include polysilicon, but is not limited thereto.

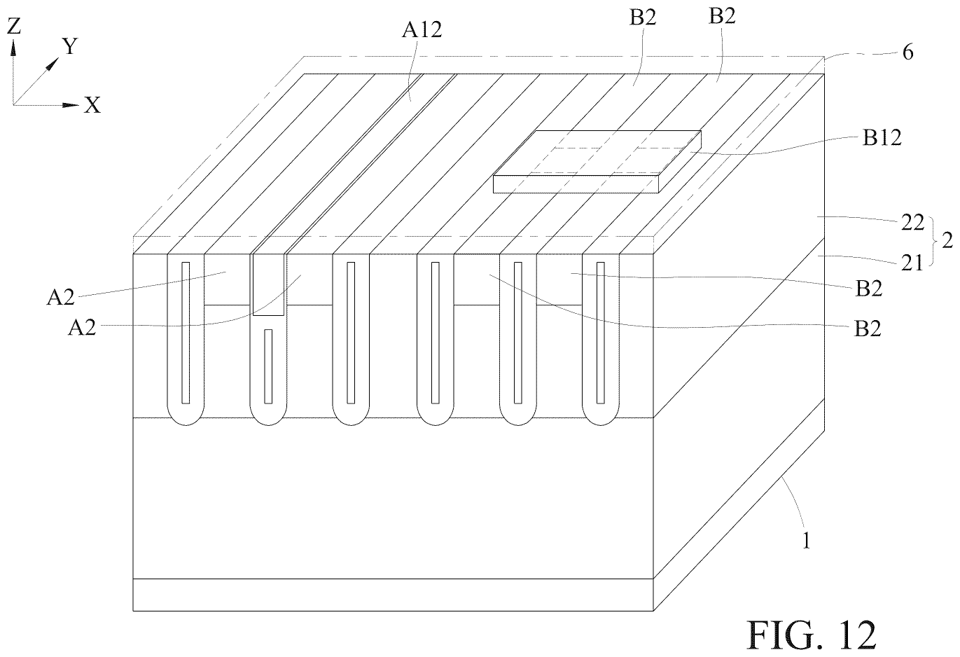

Referring to FIG. 12, in the well region forming step (S5), the two first well regions (A2) that are located in the first region of the drift layer 2 and the four second well regions (B2) that are located in the second region of the drift layer 2 are formed by doping. The two first well regions (A2) are respectively located on the two opposite sides of the trench gate electrode (A12) in the first direction (X), and have a first type conductivity. The four second well regions (B2) are formed in the two pairs which are arranged opposite to each other in the second direction (Y). In each of the two pairs, two of the four second well regions (B2) are spaced apart from each other in the first direction (X). Each of the four second well regions (B2) is disposed beneath the planar gate electrode (B12). The second well regions (B2) have the first type conductivity. In some embodiments, the first type conductivity is p-type conductivity.

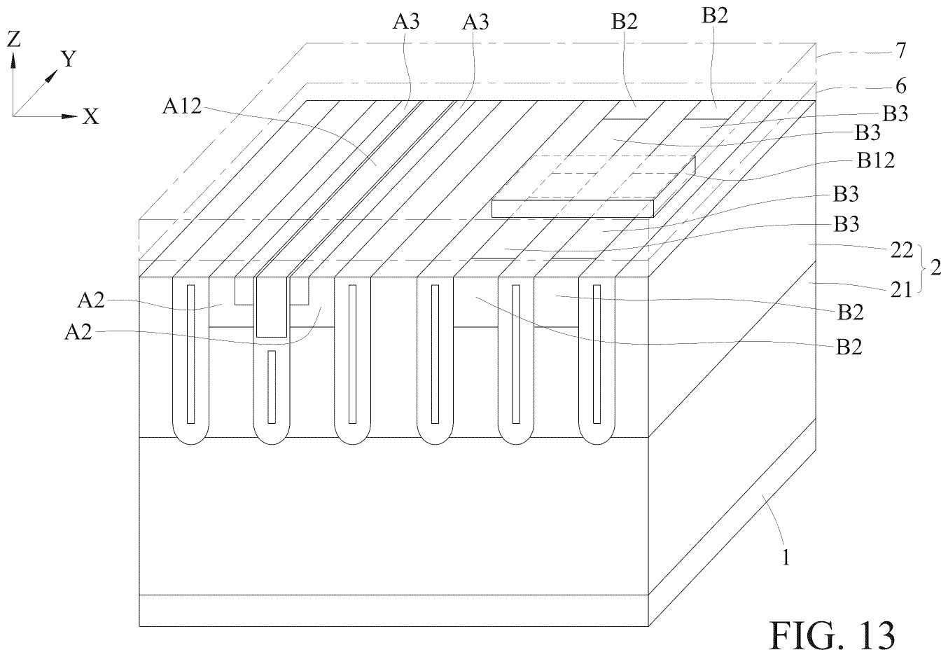

Referring to FIG. 13, in the source electrode forming step (S6), the two first source electrodes (A3) and the four second source electrodes (B3) are formed. The first source electrodes (A3) are respectively located in the first well regions (A2), and have a second type conductivity. The four second source electrodes (B3) are respectively located in the four second well regions (B2), and have the second type conductivity. Thus, the trench-type structure (A) and the planar-type structure (B) are formed. In some embodiments, the second type conductivity is n-type conductivity.

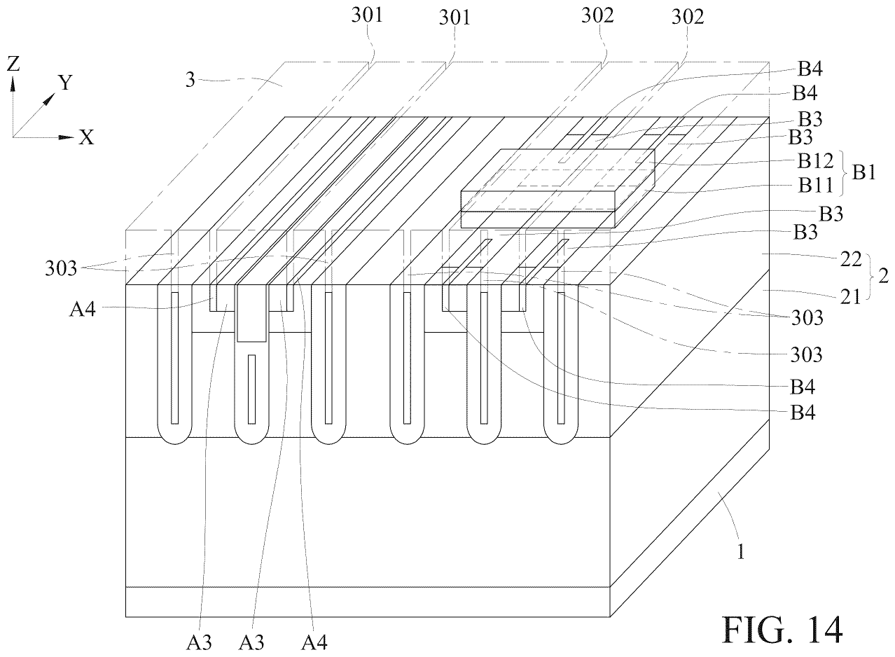

In the dielectric layer forming step (S7), an inner dielectric material is deposited on the oxide layer 6, the trench-type structure (A), and the planar-type structure (B) to form a dielectric film 7. Referring to FIG. 14, the dielectric film 7 and the oxide layer 6 are formed into the inner dielectric layer 3. In other words, the inner dielectric layer 3 covers the upper surface of the drift layer 2, the trench-type structure (A), and the planar-type structure (B). In some embodiments, the first well regions (A2), the second well regions (B2), the first source electrodes (A3), and the second source electrodes (B3) are also covered by the inner dielectric layer 3. A portion of the oxide material 6 that is located under the planar gate electrode (B12) may also be referred to as the gate oxide layer (B11). Next, the first through holes 301, the second through holes 302, and the third through holes 303 are formed in the inner dielectric layer 3 to penetrate the inner dielectric layer 3 in the third direction (Z). In some embodiments, each of the first through holes 301 and the second through holes 302 is a longitudinal groove.

In the metal layer forming step (S8), through the first through holes 301 and the second through holes 302, the first conductive layers (A4) and the second conductive layers (B4) are correspondingly formed in the first region and the second region of the drift layer 2. The first conductive layers (A4) are respectively connected to the two first source electrodes (A3). The second conductive layers (B4) are respectively connected to the four second source electrodes (B3).

Referring to FIG. 15, the conductive plugs 41 are respectively formed in the first through holes 301, the second through holes 302, and the third through holes 303. Next, the source metal layer 4 is formed on the inner dielectric layer 3. Through the conductive plugs 41, the source metal layer 4 is in electrical communication with the first conductive layers (A4), the second conductive layers (B4), the first electrode layer (A52), the second electrode layer (B52), and the third electrode layer (B62).

In some other embodiments not shown, the metal layer forming step (S8) further includes a procedure for forming fourth through holes in the inner dielectric layer 3 and a procedure for forming a gate metal layer in the inner dielectric layer 3, so that the gate metal layer is able to be in electrical communication with the trench gate electrode (A12) and the planar gate electrode (B12) through additional conductive plugs that are formed in the fourth through holes. The aforesaid procedures are well-known and may be implemented in various ways of implementation, and thus details thereof are omitted for the sake of brevity.

In the passivation layer forming step (S9), the passivation layer 5 is formed and covers the source metal layer 4.

In summary, by inclusion of the trench-type structure (A) and the planar-type structure (B) that are connected with each other in parallel in the power MOSFET, the power MOSFET of the present disclosure may exhibit a relatively low R_{DSON} and superior thermal stability so that a desired SOA may be obtained. Thus, an object of the present disclosure can indeed be achieved.

In the description above, for the purposes of explanation, numerous specific details have been set forth in order to provide a thorough understanding of the embodiment(s). It will be apparent, however, to one skilled in the art, that one or more other embodiments may be practiced without some of these specific details. It should also be appreciated that reference throughout this specification to “one embodiment,” “an embodiment,” an embodiment with an indication of an ordinal number and so forth means that a particular feature, structure, or characteristic may be included in the practice of the disclosure. It should be further appreciated that in the description, various features are sometimes grouped together in a single embodiment, figure, or description thereof for the purpose of streamlining the disclosure and aiding in the understanding of various inventive aspects; such does not mean that every one of these features needs to be practiced with the presence of all the other features. In other words, in any described embodiment, when implementation of one or more features or specific details does not affect implementation of another one or more features or specific details, said one or more features may be singled out and practiced alone without said another one or more features or specific details. It should be further noted that one or more features or specific details from one embodiment may be practiced together with one or more features or specific details from another embodiment, where appropriate, in the practice of the disclosure.

While the disclosure has been described in connection with what is(are) considered the exemplary embodiment(s), it is understood that this disclosure is not limited to the disclosed embodiment(s) but is intended to cover various arrangements included within the spirit and scope of the broadest interpretation so as to encompass all such modifications and equivalent arrangements.

What is claimed is:

1. A power metal-oxide-semiconductor field-effect transistor, comprising:
a drain electrode which has a surface extending along a first direction and a second direction perpendicular to the first direction;
a drift layer which is disposed on said drain electrode and has a first region and a second region that are arranged along the first direction;
a trench-type structure which is located at said first region of said drift layer, and which includes a gate trench that is recessed from an upper surface of said drift layer, a trench gate unit that includes a trench gate electrode located in said gate trench, two first well regions that are located in said first region of said drift layer and are respectively disposed at two opposite sides of said trench gate electrode in the first direction, and two first source electrodes that are respectively located in said two first well regions; and
a planar-type structure which is located at said second region of said drift layer, and which includes a planar gate electrode that is disposed on said second region of said drift layer, at least two second well regions that are located in said second region of said drift layer and are respectively disposed at two opposite sides of said planar gate electrode in the second direction, and at least two second source electrodes that are respectively located in said at least two second well regions, said trench-type structure and said planar-type structure being electrically connected with each other in parallel.

2. The power metal-oxide-semiconductor field-effect transistor as claimed in claim 1, wherein an area of a projection of said trench-type structure on said surface of said drain electrode is greater than an area of a projection of said planar-type structure on said surface of said drain electrode.

3. The power metal-oxide-semiconductor field-effect transistor as claimed in claim 1, wherein
said gate trench of said trench-type structure is defined by a surrounding wall, and
said trench gate unit further includes a first isolation layer made of an insulating material and extending along and covering said surrounding wall, and a shield electrode surrounded by said first isolation layer and spaced apart from said trench gate electrode in a third direction that is transverse to the first direction and the second direction, said trench gate electrode being surrounded by said first isolation layer.

4. The power metal-oxide-semiconductor field-effect transistor as claimed in claim 3, wherein said trench gate unit further includes a second isolation layer, a third isolation layer, and a fourth isolation layer, said second isolation layer and said third isolation layer being sequentially formed on said first isolation layer and being located between said first isolation layer and said shield electrode, said fourth isolation layer being located between said trench gate electrode and said first isolation layer and covering surfaces of said trench gate electrode except for an upper surface of said trench gate electrode which is away from said shield electrode.

5. The power metal-oxide-semiconductor field-effect transistor as claimed in claim 1, wherein said at least two second well regions include four second well regions, and said at least two second source electrodes include four second source electrodes, said four second well regions being formed in two pairs which are arranged opposite to each other in the second direction, and among each of said two pairs, two of said four second well regions being spaced apart from each other in the first direction, said four second source electrodes being respectively located in said four second well regions, said planar gate electrode spanning across said four second well regions.

6. The power metal-oxide-semiconductor field-effect transistor as claimed in claim 1, further comprising an inner dielectric layer that is disposed on said trench-type structure and said planar-type structure, and a source metal layer that is located on said inner dielectric layer opposite to said drift layer,
wherein said inner dielectric layer includes first through holes and second through holes that penetrate said inner dielectric layer, said power metal-oxide-semiconductor field-effect transistor including conductive plugs, each of which fills a corresponding one of said first through holes and said second through holes,
wherein said trench-type structure includes two first conductive layers that are respectively connected to said two first source electrodes,
wherein said planar-type structure includes two second conductive layers that are respectively connected to said at least two second source electrodes,
wherein said source metal layer is in electrical communication with said two first conductive layers and said two second conductive layers through said conductive plugs.

7. The power metal-oxide-semiconductor field-effect transistor as claimed in claim 1, wherein said trench-type structure further includes a first terminal structure that surrounds said trench gate unit, said two first well regions, and said two first source electrodes, said first terminal structure including a first ring-shaped trench recessed from said upper surface of said drift layer, a first insulating layer and a first electrode layer, said first insulating layer and said first electrode layer being located in said first ring-shaped trench.

8. The power metal-oxide-semiconductor field-effect transistor as claimed in claim 7, wherein said first terminal structure further includes a protection layer and a second insulating layer that are sequentially formed on said first insulating layer and are located between said first insulating layer and said first electrode layer, said protection layer being spaced apart from said first electrode layer.

9. The power metal-oxide-semiconductor field-effect transistor as claimed in claim 8, wherein said protection layer is made of a nitride-based material.

10. The power metal-oxide-semiconductor field-effect transistor as claimed in claim 7, wherein said planar-type structure further includes a second terminal structure that is formed in said drift layer to surround said at least two second well regions and said at least two second source electrodes, and that is disposed beneath said planar gate electrode,
wherein said second terminal structure includes a second ring-shaped trench recessed from said upper surface of said drift layer, a second insulating layer and a second electrode layer, said second insulating layer and said second electrode layer being located in said second ring-shaped trench.

11. The power metal-oxide-semiconductor field-effect transistor as claimed in claim 10, wherein said at least two second well regions include four second well regions, and said at least two second source electrodes include four second source electrodes, said four second well regions being formed in two pairs that are spaced apart from each other in the second direction, said four second source electrodes being respectively located in said four second well regions and formed in two pairs corresponding to the two pairs of the second well regions, said planar-type structure further including a third terminal structure that separates said second well regions of each of said two pairs of said four second well regions and separates said second source electrodes of each of said two pairs of said four second source electrodes, said third terminal structure being surrounded by said second terminal structure and having a groove recessed from said upper surface of said drift layer, a third insulating layer, and a third electrode layer, said third insulating layer and said third electrode layer being located in said groove, said planar gate electrode being disposed on said third terminal structure.

12. The power metal-oxide-semiconductor field-effect transistor as claimed in claim 11, wherein in the first direction, said first ring-shaped trench and said gate trench are separated from each other by a first distance, said first ring-shaped trench and said second ring-shaped trench are separated from each other by a second distance, and said second ring-shaped trench and said groove are separated from each other by a third distance, the first distance, the second distance, and third distance being identical.

13. The power metal-oxide-semiconductor field-effect transistor as claimed in claim 11, wherein said drift layer further has a third region that is located between said first region and said second region and between said first ring-shaped trench and said second ring-shaped trench.

14. method for manufacturing a power metal-oxide-semiconductor field-effect transistor, comprising:
forming a drift layer on a surface of a drain electrode, the surface of the drain electrode extending along a first direction and a second direction perpendicular to the first direction, the drift layer having a first region and a second region that are arranged along the first direction;
etching the drift layer along a third direction that is transverse to the first direction and the second direction to form a gate trench in the first region of the drift layer;
forming a trench gate electrode in the gate trench and a planar gate electrode on the second region of the drift layer;
forming two first well regions that are located in the first region of the drift layer, that are respectively disposed at two opposite sides of the trench gate electrode in the first direction, and that have a first type conductivity;
forming two second well regions that are located in the second region of the drift layer, that are respectively disposed at two opposite sides of the planar gate electrode in the second direction, and that have the first type conductivity;
forming two first source electrodes that are respectively located in the two first well regions and that have a second type conductivity; and
forming two second source electrodes that are respectively located in the two second well regions and that have the second type conductivity.

15. The method as claimed in claim 14, wherein the trench gate electrode and the planar gate electrode are formed by:
depositing an oxide material on the drift layer to form an oxide layer;
forming a groove in the oxide layer, the groove being registered with the gate trench to expose the gate trench;
depositing a gate electrode material in the gate trench and on the oxide layer; and
removing a portion of the gate electrode material on the oxide layer so as to form the trench gate electrode in the gate trench and the planar gate electrode on the second region of the drift layer.

16. The method as claimed in claim 14, wherein the first type conductivity is p-type conductivity and the second type conductivity is n-type conductivity.

17. The method as claimed in claim 14, further comprising:
forming an inner dielectric layer to cover an upper surface of the drift layer, the trench gate electrode, the planar gate electrode, the two first well regions, the two second well regions, the two first source electrodes, and the two second source electrodes;
forming first through holes and second through holes in the inner dielectric layer to penetrate the inner dielectric layer in the third direction;
forming first conductive layers and second conductive layers in the first region and the second region of the drift layer, respectively, the first conductive layers being respectively connected to the two first source electrodes, the second conductive layers being respectively connected to the two second source electrodes;
forming conductive plugs in the first through holes and the second through holes, respectively; and
forming a source metal layer on the inner dielectric layer, the source metal layer being in electrical communication with the first conductive layers and the second conductive layers though the conductive plugs.

18. The method as claimed in claim 14, wherein each of the trench gate electrode and the planar gate electrode is made of a polysilicon material.
